(19) United States
(12) Patent Application Publication
(10) Pub. No.: US 2024/0170614 A1
(43) Pub. Date: May 23, 2024

(54) LIGHT-EMITTING ELEMENT, METHOD OF FORMING THE LIGHT-EMITTING ELEMENT, AND DISPLAY DEVICE

(71) Applicant: Samsung Display Co., LTD., Yongin-si (KR)

(72) Inventors: Mi Hyang SHEEN, Yongin-si (KR); Dong Uk KIM, Yongin-si (KR); Kwan Jae LEE, Yongin-si (KR); Bo Hwa KIM, Yongin-si (KR); Dong Youn YOO, Yongin-si (KR); Hyeong Su CHOI, Yongin-si (KR)

(21) Appl. No.: 18/459,325

(22) Filed: Aug. 31, 2023

(30) Foreign Application Priority Data
Nov. 22, 2022 (KR) 10-2022-0157655

(51) Int. Cl. H01L 33/38; H01L 25/075; H01L 33/24; H01L 33/50; H01L 33/62

(52) U.S. Cl. CPC H01L 33/382; H01L 25/0753; H01L 33/24; H01L 33/502; H01L 33/62; H01L 2933/0016; H01L 2933/0041

(57) ABSTRACT

A light-emitting element comprises a first semiconductor layer, an active layer provided on the first semiconductor layer, a second semiconductor layer provided on the active layer, an electrode layer provided on the second semiconductor layer, and an insulating film around outer peripheral surfaces of the first semiconductor layer, the active layer, the second semiconductor layer, and the electrode layer, wherein the active layer includes a cover layer including a plurality of quantum dots, and the first semiconductor layer, the active layer, the second semiconductor layer, and the electrode layer are sequentially stacked in one direction to form a shape of a rod.

### CROSS-REFERENCE TO RELATED APPLICATION

This application claims priority to and the benefit of Korean Patent Application No. 10-2022-0157655 filed on Nov. 22, 2022, in the Korean Intellectual Property Office, the entire content of which is herein incorporated by reference.

### BACKGROUND

### 1. Field

One or more embodiments of the present disclosure relate to a light-emitting element, a method of forming the light-emitting element, and a display device.

### 2. Description of the Related Art

Display devices are becoming more important with developments in multimedia technology. Accordingly, various display devices such as an organic light-emitting diode (OLED) display device, a liquid crystal display (LCD) device, and the like have been used.

Among examples of the display devices, which display an image, is a light-emitting display device having light-emitting elements. Examples of the light-emitting display device include an organic light-emitting display device using an organic material as a light-emitting material and an inorganic light-emitting display device using an inorganic material as a light-emitting material.

### SUMMARY

One or more aspects of embodiments of the present disclosure provide a light-emitting element capable of improving luminous efficiency, a method of forming the light-emitting element, and a display device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, a light-emitting element comprises a first semiconductor layer, an active layer on the first semiconductor layer, a second semiconductor layer on the active layer, an electrode layer on the second semiconductor layer, and an insulating film around outer peripheral surfaces of the first semiconductor layer, the active layer, the second semiconductor layer, and the electrode layer, wherein the active layer includes a cover layer including a plurality of quantum dots, and the first semiconductor layer, the active layer, the second semiconductor layer, and the electrode layer are sequentially stacked in one direction to form a shape of a rod.

In one or more embodiments, the light-emitting element is formed in a shape of a cylindrical rod or a hexagonal rod.

In one or more embodiments, a diameter of the rod is in a range of 0.2 μm to 1 μm.

In one or more embodiments, the plurality of quantum dots and the cover layer include InₓGa₁₋ₓN where x is 0.1 to 0.3.

In one or more embodiments, an indium (In) content of the plurality of quantum dots is different from an indium (In) content of the cover layer.

In one or more embodiments, the In content of the plurality of quantum dots is greater than the In content of the cover layer.

In one or more embodiments, the plurality of quantum dots are spaced apart at random intervals.

In one or more embodiments, a thickness of each of the plurality of quantum dots is in a range of 1 nm to 5 nm.

In one or more embodiments, a size of each of the plurality of quantum dots is in a range of 1 nm to 500 nm.

In one or more embodiments, the active layer has a structure in which a plurality of cover layers, each of the plurality of cover layers including a plurality of quantum dots, are stacked.

According to one or more embodiments of the present disclosure, a method of forming a light-emitting element, comprises forming a buffer layer on a base substrate, forming a first semiconductor material layer on the buffer layer, forming a cover layer including a plurality of quantum dots, to form an active material layer on the first semiconductor material layer, forming a second semiconductor material layer on the active material layer, forming an electrode material layer on the second semiconductor material layer, forming a light-emitting element core by etching the first semiconductor material layer, the active material layer, the second semiconductor material layer, and the electrode material layer, forming an insulating film around the light-emitting element core, and separating the light-emitting core and the insulating film from the buffer layer.

In one or more embodiments, the forming the active material layer, comprises forming the plurality of quantum dots by lowering the temperature while forming the cover layer on the first semiconductor material layer.

In one or more embodiments, the plurality of quantum dots are formed at a temperature of more than or equal to 600° C. to less than 680° C.

In one or more embodiments, the light-emitting element core includes a first semiconductor layer, an active layer, a second semiconductor layer, and an electrode layer, and the insulating film is around outer peripheral surfaces of the first semiconductor layer, the active layer, the second semiconductor layer, and the electrode layer.

In one or more embodiments, the light-emitting element core is formed in a shape of a cylindrical rod or a hexagonal rod.

According to one or more embodiments of the present disclosure, a display device comprises a substrate, a first electrode and a second electrode provided on the substrate spaced apart from each other, the first electrode and the second electrode extending substantially in parallel to each other, an insulating layer provided on the first electrode and the second electrode, light-emitting elements on the insulating layer and aligned on the first electrode and the second electrode, and a first connection electrode connected to first end portions of the light-emitting elements and a second connection electrode connected to second end portions of the light-emitting elements, wherein each of the light-emitting elements includes a first semiconductor layer, an active layer on the first semiconductor layer, a second semiconductor layer on the active layer, an electrode layer on the second semiconductor layer, and an insulating film around outer peripheral surfaces of the first semiconductor layer, the active layer, the second semiconductor layer, and the electrode layer, the active layer includes a cover layer including a plurality of quantum dots, and the first semiconductor layer, the active layer, the second semiconductor layer, and the electrode layer are sequentially stacked in one direction to form a shape of a rod.

In one or more embodiments, the light-emitting element is formed in a shape of a cylindrical rod or a hexagonal rod.

In one or more embodiments, the plurality of quantum dots and the cover layer include InₓGa₁₋ₓN where x is 0.1 to 0.3, and an indium (In) content of the plurality of quantum dots is different from an indium (In) content of the cover layer.

In one or more embodiments, a thickness of each of the plurality of quantum dots is in a range of 1 nm to 5 nm, and a size of each of the plurality of quantum dots is in a range of 1 nm to 500 nm.

In one or more embodiments, the active layer has a structure in which a plurality of cover layers, each of the plurality of cover layers including a plurality of quantum dots, are stacked.

According to the aforementioned and other embodiments of the present disclosure, as the flow of carriers out of quantum dots through the contact surfaces of the quantum dots and the side surface of an active layer can be prevented or reduced, a decrease in the luminous efficiency of the light-emitting element can be prevented or reduced. Also, as the quantum dots are spaced apart from one another, carriers can be confined within the quantum dots, and the luminous efficiency of the light-emitting element can be improved.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in more detail embodiments thereof with reference to the attached drawings, in which:

FIG. 1 is a perspective view of a light-emitting element according to one or more embodiments of the present disclosure;

FIG. 2 is a cross-sectional view of the light-emitting element of FIG. 1;

FIG. 3 is an enlarged cross-sectional view of an area A of FIG. 2;

FIG. 4 is an image of an active layer of the light-emitting element of FIG. 1;

FIG. 5 is a graph showing the emission spectra of quantum dots and a cover layer of the active layer of the light-emitting element of FIG. 1;

FIG. 6 is a schematic view illustrating the energy bandgap of the quantum dots of the active layer of the light-emitting element of FIG. 1;

FIG. 7 is a schematic view illustrating the energy bandgap of the cover layer of the active layer of the light-emitting element of FIG. 1;

FIG. 8 is a cross-sectional view of an active layer of a light-emitting element according to one or more embodiments of the present disclosure;

FIGS. 9-14 are cross-sectional views illustrating a method of forming a light-emitting element according to one or more embodiments of the present disclosure;

FIG. 15 is a plan view of a display device according to one or more embodiments of the present disclosure;

FIG. 16 is a plan view of a pixel of the display device of FIG. 15;

FIG. 17 is a cross-sectional view taken along line E1-E1′ of FIG. 16; and

FIG. 18 is a cross-sectional view taken along line E2-E2′ of FIG. 16.

### DETAILED DESCRIPTION

The present disclosure will now be described more fully hereinafter with reference to the accompanying drawings, in which embodiments of the present disclosure are shown. This disclosure may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate (e.g., without any intervening layers therebetween), or one or more intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

As used herein, the singular forms “a,” “an,” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

Spatially relative terms , such as “beneath,” “below ,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Embodiments of the present disclosure will hereinafter be described with reference to the attached drawings.

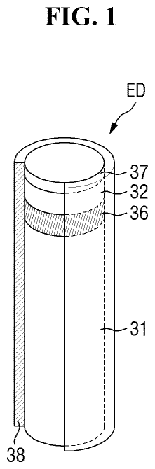

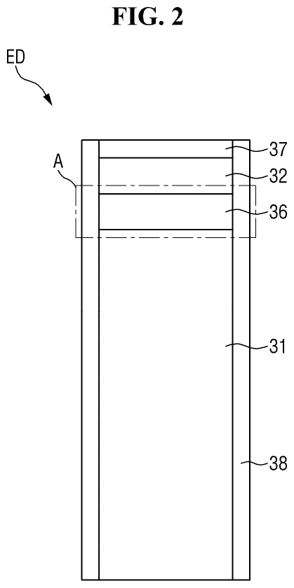

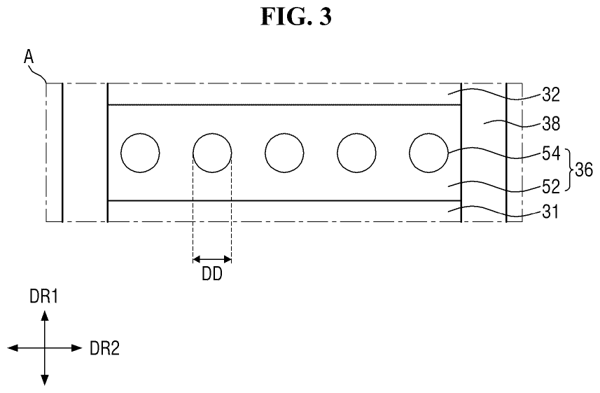

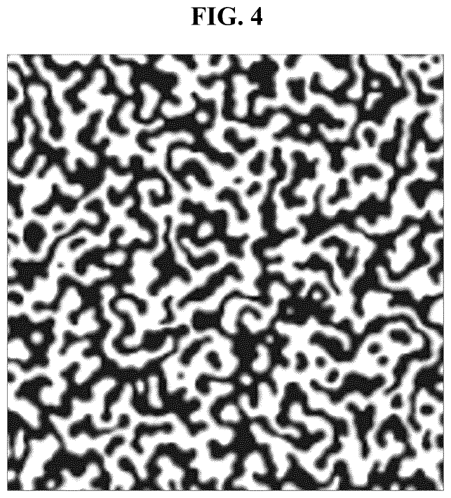

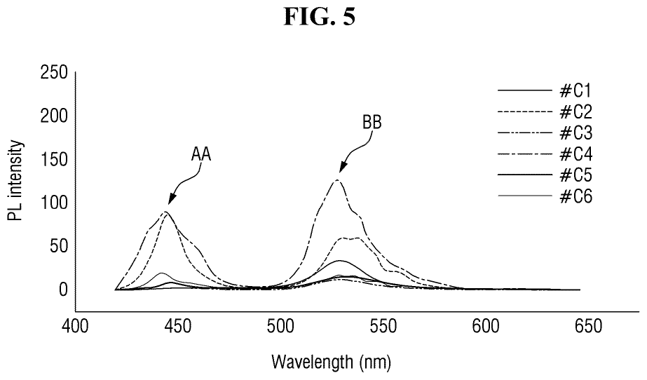

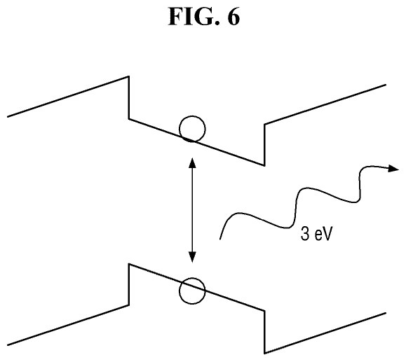

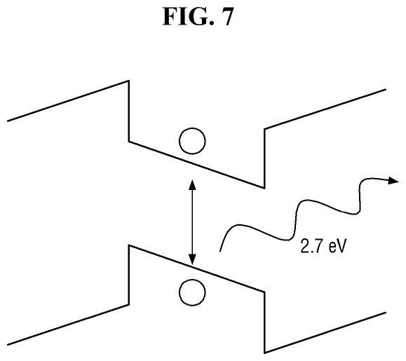

FIG. 1 is a perspective view of a light-emitting element according to one or more embodiments of the present disclosure. FIG. 2 is a cross-sectional view of the light-emitting element of FIG. 1. FIG. 3 is an enlarged cross-sectional view of an area A of FIG. 2. FIG. 4 is an image of an active layer of the light-emitting element of FIG. 1. FIG. 5 is a graph showing the emission spectra of quantum dots and a cover layer of the active layer of the light-emitting element of FIG. 1. FIG. 6 is a schematic view illustrating the energy bandgap of the quantum dots of the active layer of the light-emitting element of FIG. 1. FIG. 7 is a schematic view illustrating the energy bandgap of the cover layer of the active layer of the light-emitting element of FIG. 1.

Referring to FIGS. 1 through 3, a light-emitting element ED may be a light-emitting diode (LED), for example, an inorganic LED having a size of several nanometers or micrometers and formed of an inorganic material. The light-emitting element ED may be aligned between two opposing electrodes (e.g., two electrodes facing each other) by forming an electric field in a set or particular direction between the two opposing electrodes.

The light-emitting element ED may extend in one direction. The light-emitting element ED may have the shape of a cylindrical or hexagonal rod, wire, and/or a tube. For example, the light-emitting element ED may have the shape of a rod whose diameter is in a range of 0.2 μm to 1 μm. Here, the diameter of the rod refers to the diameter of the upper or lower surface of the rod.

The light-emitting element ED may include semiconductor layers doped with a dopant of an arbitrary or set conductivity type (e.g., a p type or an n type). The semiconductor layers receive electrical signals from an external power source and may thus emit light of a set or particular wavelength range. The light-emitting element ED may include a first semiconductor layer 31, a second semiconductor layer 32, an active layer 36, an electrode layer 37, and an insulating film 38.

The first semiconductor layer 31 may include an n-type semiconductor. The first semiconductor layer 31 may include a semiconductor material, e.g., AlₓGa_{y}In_{1-x-y}N (where 0≤x≤1, 0≤y≤1, and 0≤x+y≤1). For example, the first semiconductor layer 31 may include at least one selected from among AlGalnN, GaN, AlGaN, InGaN, AlN, and InN that are doped with an n-type dopant. The first semiconductor layer 31 may be doped with an n-type dopant, and the n-type dopant may be Si, Ge, and/or Sn.

The second semiconductor layer 32 is provided on the first semiconductor layer 31, and the active layer 36 is provided between the first and second semiconductor layers 31 and 32. The second semiconductor layer 32 may include a p-type semiconductor. The second semiconductor layer 32 may include a semiconductor material, e.g., AlₓGa_{y}In_{1-x-y}N (where 0≤x≤1, 0sy≤1, and 0≤x+y≤1). For example, the second semiconductor layer 32 may include at least one selected from among AlGaInN, GaN, AlGaN, InGaN, AlN, and InN that are doped with a p-type dopant, and the p-type dopant may be Mg, Zn, Ca, and/or Ba.

The first and second semiconductor layers 31 and 32 are illustrated as being single layers, but the present disclosure is not limited thereto. In some embodiments, each of the first and second semiconductor layers 31 and 32 may include more than one layer such as, for example, a clad layer and/or a tensile strain barrier reducing (TSBR) layer, depending on the material of the light-emitting layer 36. For example, the light-emitting element ED may include another semiconductor layer between the first semiconductor layer 31 and the active layer 36, or between the second semiconductor layer 32 and the active layer 36. The semiconductor layer between the first semiconductor layer 31 and the active layer 36 may include at least one selected from among AlGaInN, GaN, AlGaN, InGaN, AlN, and InN, that are doped with an n-type dopant, and the semiconductor layer between the second semiconductor layer 32 and the active layer 36 may include at least one selected from among AlGaInN, GaN, AlGaN, InGaN, AlN, and InN that are doped with a p-type dopant.

The active layer 36 is provided between the first and second semiconductor layers 31 and 32. The active layer 36 may emit light through the combination of electrons and holes in response to electrical signals applied thereto through the first and second semiconductor layers 31 and 32.

The active layer 36 may include a plurality of quantum dots 54 and a cover layer 52, which covers the quantum dots 54.

The quantum dots 54 may be randomly (e.g., substantially non-uniformly) distributed in the cover layer 52. Referring to FIG. 3, the quantum dots 54 may be spaced apart from one another. The quantum dots 54 may have a circular, elliptical, linear, or amorphous random shape in a plan view.

The quantum dots 54 may be formed of InGaN. The quantum dots 54 may include, for example, InₓGa₁₋ₓN (0.1≤x≤0.3). The quantum dots 54 may have a thickness of 1 nm to 5 nm. The quantum dots 54 may have a size of 1 nm to 500 nm. Here, the thickness of the quantum dots 54 refers to the length (e.g., measurement), in a first direction DR1, of each of the quantum dots 54, and the size of the quantum dots 54 refers to the length (e.g., measurement), in a second direction DR2, of each of the quantum dots 54. The quantum dots 54 are illustrated as having a circular shape, but the present disclosure is not limited thereto.

The cover layer 52 may be a layer in which the quantum dots 54 are distributed. The cover layer 52 may completely surround the quantum dots 54. For example, the quantum dots 54 may be embedded in the cover layer 52. The cover layer 52 may include InGaN. For example, the cover layer 52 may include, for example, InₓGa₁₋ₓN (0.1≤x≤0.3). The cover layer 52 may have a thickness of 1 nm to 10 nm.

The quantum dots 54 may have a different indium (In) content from that of the cover layer 52. For example, the In content of the quantum dots 54 may be greater than the In content of the cover layer 52. The quantum dots 54 may be parts of the active layer 36 that are grown first due to the concentration of stress during the formation of the active layer 36 and may thus have a greater In content than the cover layer 52.

The light-emitting element ED may include the active layer 36, and the active layer 36 may include the cover layer 52, in which the quantum dots 54 are distributed. During the driving of the light-emitting element ED, carriers are concentrated on the quantum dots 54. For example, if the light-emitting element ED has a rod shape and the quantum dots 54 are provided on the side surface of the active layer 36 that is in contact with an insulating film 38, carriers flow out of the quantum dots 54 through the side surface of the active layer 36, thereby causing a leakage current and lowering the luminous efficiency of the light-emitting element ED. As the quantum dots 54 are distributed in the cover layer 52, the contact areas of the quantum dots 54 and the side surface of the active layer 36 can be reduced, and as a result, a decrease in the luminous efficiency of the light-emitting element ED can be prevented or reduced. Also, as the quantum dots 54 are spaced apart from one another, carriers can be confined (or substantially confined) within the quantum dots 54 without flowing out of the quantum dots 54. As a result, carriers can be concentrated within (or substantially within) the quantum dots 54, and the luminous efficiency of the light-emitting element ED can be improved.

FIG. 5 shows the emission spectra of the quantum dots 54 and the cover layer 52 in the active layer 36. Referring to FIG. 5, lines #C1 through #C6 represent a plurality of light-emitting elements ED. For example, FIG. 5 shows the emission spectra of active layers 36 of a plurality of light-emitting elements ED. FIG. 6 illustrates the energy bandgap of the quantum dots 54, and FIG. 7 illustrates the energy bandgap of the cover layer 52.

An emission spectrum AA of the quantum dots 54 may have a peak wavelength of about 445 nm, and an emission spectrum BB of the cover layer 52 may have a peak wavelength of about 530 nm. As the quantum dots 54 and the cover layer 52 have different In contents, the quantum dots 54 and the cover layer 52 have different energy bandgaps and thus have different emission wavelength ranges. For example, the quantum dots 54 may have an energy bandgap of about 3 eV and may emit light of a peak wavelength of 445 nm, and the cover layer 52 may have an energy bandgap of about 2.7 eV and may emit light of a peak wavelength of 530 nm. As the quantum dots 54 and the cover layer 52 of the active layer 36 have different In contents, the active layer 36 may emit light of different wavelength ranges.

The wavelength range of light emitted by the active layer 36 may be controlled by controlling the size of the quantum dots 54 or forming the active layer 36 as a stack of multiple layers.

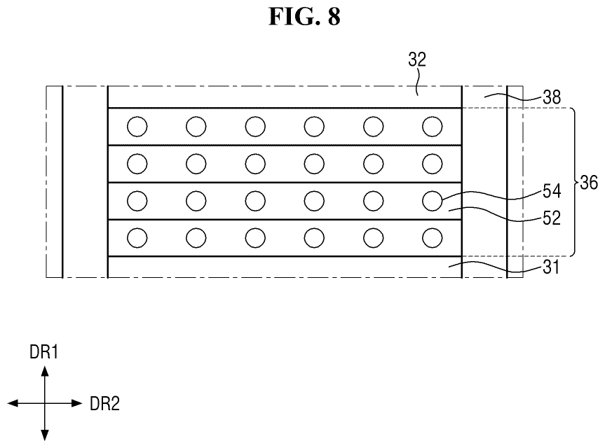

FIG. 8 is a cross-sectional view of an active layer of a light-emitting element according to one or more embodiments of the present disclosure.

Referring to FIG. 8, an active layer 36 may have a structure in which a plurality of active layers 52 with a plurality of quantum dots 54 distributed therein are stacked. Quantum dots 54 adjacent to one another in a first direction DR1 or a second direction DR2 may be electrically coupled. As the number of cover layers 52 with the quantum dots 54 included therein increases, the size of the quantum dots 54 may substantially increase, the energy bandgap of the quantum dots 54 may decrease, and the emission spectrum of the quantum dots 54 may increase. Accordingly, by suitably controlling the number of cover layers 52 with the quantum dots 54 included therein, the active layer 36 may be configured to emit light of various wavelength ranges from a blue wavelength range to a red wavelength range.

Referring again to FIGS. 1 through 3, the electrode layer 37 may be an ohmic connection electrode, but the present disclosure is not limited thereto. In some embodiments, the electrode layer 37 may be a Schottky connection electrode. The light-emitting element ED may include at least one electrode layer 37, but the present disclosure is not limited thereto. The electrode layer 37 may be optional (e.g., may not be provided).

The electrode layer 37 may lower the resistance between the light-emitting element ED and an electrode or a connection electrode when the light-emitting element ED is electrically connected to the electrode or the connection electrode. The electrode layer 37 may include a conductive metal. For example, the electrode layer 37 may include at least one selected from among aluminum (Al), titanium (Ti), indium (In), gold (Au), silver (Ag), indium tin oxide (ITO), indium zinc oxide (IZO), and indium tin zinc oxide (ITZO).

The insulating film 38 is provided to surround the semiconductor layers and the electrode layer 36 of the light-emitting element ED. For example, the insulating film 38 may be provided to surround the outer surface (e.g., outer peripheral surface) of at least the active layer 36, but to expose both ends, in a length direction, of the light-emitting element ED. The insulating film 38 may be formed to have a rounded top surface in a region adjacent to at least one end of the light-emitting element ED.

The insulating film 38 may include at least one insulating material such as, for example, silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and/or titanium oxide (TiOₓ). The insulating film 38 is illustrated as being a single layer, but the present disclosure is not limited thereto. In some embodiments, the insulating film 38 may be a multilayer in which multiple layers are stacked.

The insulating film 38 may protect the semiconductor layers and the electrode layer 37 of the light-emitting element ED. The insulating film 38 can prevent or reduce an electrical short circuit that may occur in the active layer 36 when the light-emitting element ED is placed in direct contact with an electrode, to which electrical signals are transmitted. Also, the insulating film 38 can prevent or reduce the decrease in the luminous efficiency of the light-emitting element ED.

The outer surface of the insulating film 38 may be surface-treated. The light-emitting element ED may be sprayed and aligned on an electrode while being dispersed in set or predetermined ink. Here, the outer surface (e.g., the outer peripheral surface) of the insulating film 38 may be hydrophobically or hydrophilically surface-treated such that the light-emitting element ED may be maintained to be dispersed (e.g., in a dispersed state), rather than agglomerating with other neighboring light-emitting elements ED in the ink.

A method of forming a light-emitting element according to one or more embodiments of the present disclosure will hereinafter be described.

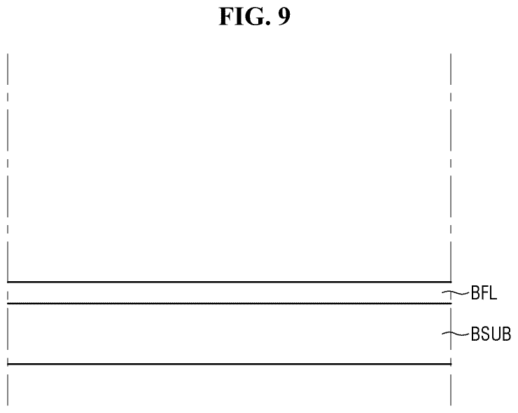

FIGS. 9 through 14 are cross-sectional views illustrating a method of forming a light-emitting element according to one or more embodiments of the present disclosure.

Referring to FIG. 9, a buffer layer BFL is formed on a base substrate BSUB.

For example, the base substrate BSUB is prepared. The base substrate BSUB may be a sapphire (Al₂O₃) substrate and/or a silicon (Si) wafer, but the present disclosure is not limited thereto. In some embodiments, the base substrate BSUB may be a conductive substrate formed of GaN, SiC, ZnO, Si, GaP, and/or GaAs. The base substrate BSUB will hereinafter be described as being, for example, a sapphire substrate. The thickness of the base substrate BSUB is not particularly limited. For example, the base substrate BSUB may have a thickness in a range of 400 μm to 1500 μm.

Thereafter, the buffer layer BFL is formed on the base substrate BSUB. The buffer layer BFL is illustrated as being a single layer, but the present disclosure is not limited thereto. In some embodiments, the buffer layer BFL may be formed as a multilayer. The buffer layer BFL may be provided to reduce the difference in lattice constant between the base substrate BSUB and a first semiconductor material layer SLL1 that will be described in more detail herein below.

For example, the buffer layer BFL may include an undoped semiconductor. The buffer layer BFL may include substantially the same material as the first semiconductor material layer SLL1, for example, a material not doped with an n-type dopant or a p-type dopant. The buffer layer BFL may include at least one selected from among InAlGaN, GaN, AlGaN, InGaN, AlN, and InN that are not doped, but the present disclosure is not limited thereto. The buffer layer BFL may be optional (e.g., may not be provided). The buffer layer BFL will hereinafter be described as being formed on the base substrate BSUB and including an undoped semiconductor.

Semiconductor material layers including the buffer layer BFL may be grown by an epitaxial growth method and may be formed by growing seed crystals. Here, the semiconductor material layers may include an active material layer SLL2. The semiconductor material layers may be formed by electron beam deposition, physical vapor deposition (PVD), chemical vapor deposition (CVD), plasma laser deposition (PLD), dual-type thermal evaporation, sputtering, and/or metal-organic chemical vapor deposition (MOCVD), for example, by MOCVD, but the present disclosure is not limited thereto.

A precursor material for forming the semiconductor material layers is not particularly limited. For example, the precursor material may be a metal precursor including an alkyl group such as a methyl and/or ethyl group. For example, the precursor material may be a compound such as trimethyl gallium (Ga(CH₃)₃), trimethyl aluminum (AI(CH₃)₃), trimethyl indium (In(CH₃)₂), and/or triethyl phosphate ((C₂H₅)₃PO₄), but the present disclosure is not limited thereto.

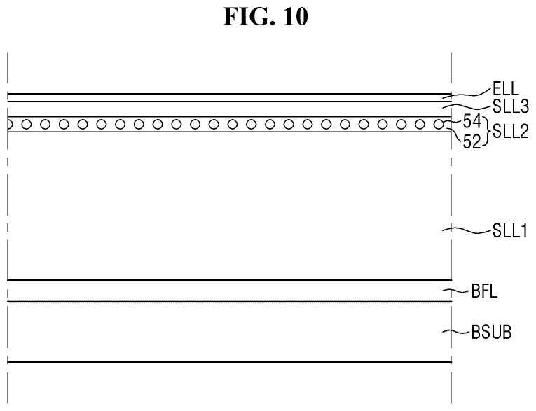

Thereafter, referring to FIG. 10, the first semiconductor material layer SLL1, the active material layer SLL2, a second semiconductor material layer SLL3, and an electrode material layer ELL are sequentially formed on the buffer layer BFL. As already mentioned above, the first semiconductor material layer SLL1, the second semiconductor material layer SLL3, and the electrode material layer ELL may be formed by a suitable method.

The active material layer SLL2 may be formed to include a cover layer 52 in which a plurality of quantum dots 54 are distributed.

1 In one or more embodiments, the first semiconductor material layer SLL1 may be formed, and an InGaN cover layer 52 may be formed via epitaxial growth using Ga(CH₃)₃, In(CH₃)₂, and/or ammonia. Thereafter, when the cover layer 52 reaches a set or predetermined thickness, the temperature may be lowered, thereby growing the quantum dots 54. It is advantageous to have a large lattice mismatch to grow the quantum dots 54. To this end, the difference between the temperature for forming the cover layer 52 and the temperature for growing the quantum dots 54 may be widened. For example, the cover layer 52 may be grown at a temperature of about 680° C., and the quantum dots 54 may be grown at a temperature of about 600° C. to 680° C.

Thereafter, after the formation of the quantum dots 54, the temperature may be raised again, and the cover layer 52 may be grown. As a result, as illustrated in FIG. 10, an active material layer SLL2 including a plurality of quantum dots 54 distributed in the cover layer 52 is formed. In embodiments where the active material layer SLL2 has a multilayer structure, the aforementioned processes of growing the quantum dots 54 and forming the cover layer 52 may be repeatedly performed.

The layers formed on the buffer layer BFL may correspond to the layers of each of a plurality of light-emitting elements ED to be formed. For example, the first semiconductor material layer SLL1, the active material layer SLL2, the second semiconductor material layer SLL3, and the electrode material layer ELL may include the same material as a first semiconductor layer 31, an active layer 36, a second semiconductor layer 32, and an electrode layer 37, respectively, of each of the light-emitting elements ED to be formed.

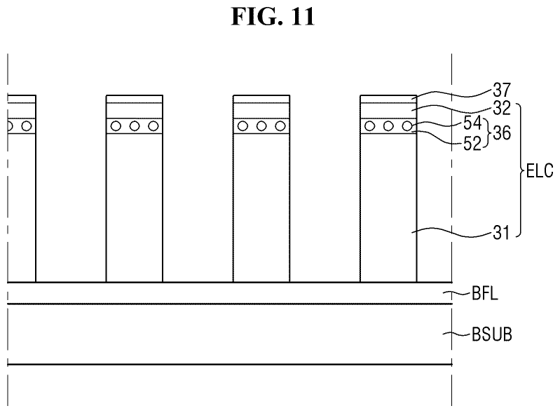

Thereafter, referring to FIG. 11, a plurality of light-emitting element cores ELC, which are spaced apart from one another, are formed by performing a first etching process on the layers stacked on the buffer layer BFL.

In one or more embodiments, holes are formed by performing the first etching process, which etches parts of the first semiconductor material layer SLL1, the active material layer SLL2, the second semiconductor material layer SLL3, and the electrode material layer ELL on the buffer layer BFL, and as a result, the light-emitting element cores ELC, which are spaced apart from one another by the holes, are obtained.

The first etching process may be performed by a suitable method. For example, the first etching process may be performed by forming an etching mask layer and performing etching in a direction perpendicular (or substantially perpendicular) to the base substrate BSUB, along the etching mask layer.

For example, the first etching process may be dry etching, wet etching, reactive ion etching (RIE), and/or inductively coupled plasma-reactive ion etching (ICP-RIE). Dry etching may enable anisotropic etching and may thus be suitable as vertical etching. In the first etching process, Cl₂ and/or O₂ may be used as an etchant, but the present disclosure is not limited thereto. The first semiconductor material layer SLL1, the active material layer SLL2, the second semiconductor material layer SLL3, and the electrode material layer ELL may be formed by performing dry etching in a depth direction.

Each of the light-emitting element cores ELC may include a first semiconductor layer 31, an active layer 36, a second semiconductor layer 32, and an electrode layer 37, which are stacked on the buffer layer BFL. The light-emitting element cores ELC may be formed as cylindrical or hexagonal rods.

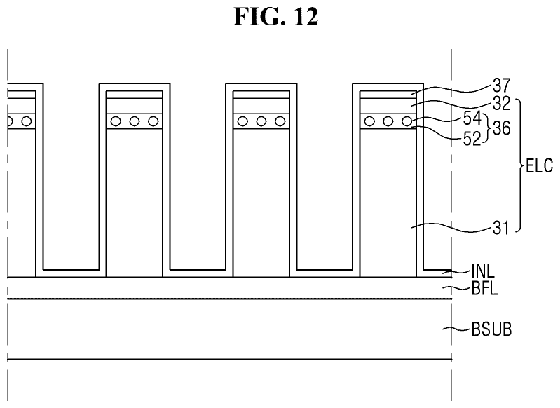

Thereafter, referring to FIG. 12, an insulating material layer INL, which surrounds the light-emitting element cores ELC, is formed.

In one or more embodiments, the insulating material layer INL may be formed to completely cover the side surfaces of the light-emitting element cores ELC and the top surfaces and the side surfaces of electrode layers 37. The insulating material layer INL may be formed on the entire surface of the base substrate BSUB and even on parts of the buffer layer BFL exposed by the light-emitting element cores ELC.

The insulating material layer INL may include the same insulating material as the insulating films 38 of the light-emitting element cores ELC. The insulating material layer INL may be formed by applying and/or immersing an insulating material on the top surfaces and the side surfaces of the light-emitting element cores ELC, but the present disclosure is not limited thereto. For example, the insulating material layer INL may be formed by atomic layer deposition (ALD). The insulating material layer INL is illustrated as being formed as a single layer, but the present disclosure is not limited thereto.

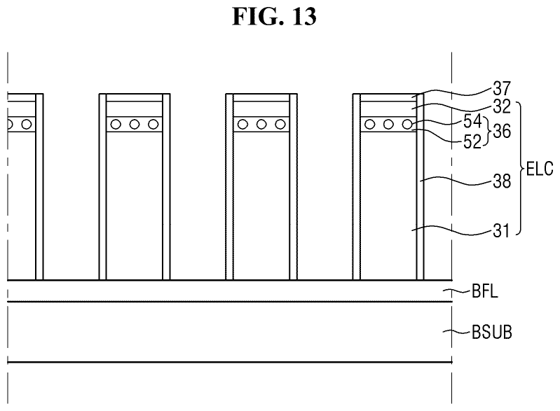

Thereafter, referring to FIG. 13, insulating films 38 are formed by performing a second etching process to remove parts of the insulating material layer INL.

The top surfaces and the side surfaces (or the top surfaces and a portion of the side surfaces, or only the top surfaces) of the electrode layers 37 are exposed by performing the second etching process to remove parts of the insulating material layer INL. The removal of parts of the insulating material layer INS may be performed by a dry etching process and/or an etch-back process, which is an anisotropic etching process. As a result of the second etching process, parts of the insulating material layer INL may be removed so that the top surfaces and the side surfaces (or the top surfaces and a portion of the side surfaces, or only the top surfaces) of the electrode layers 37 are exposed, but parts of the insulating material layer INL that surround the side surfaces of the light-emitting element cores ELC may not be removed.

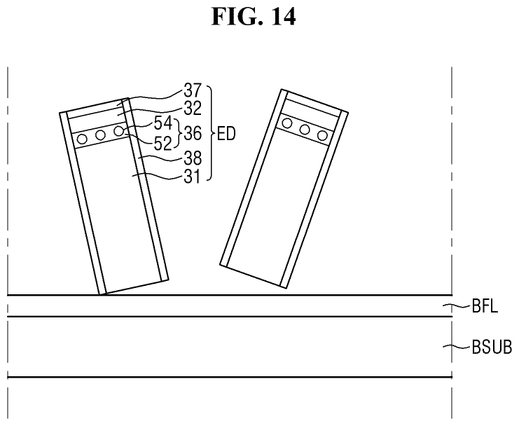

Thereafter, referring to FIG. 14, the light-emitting element cores ELC, in which the electrode layers 37 and the insulating films 38 are formed, are separated from the base substrate BSUB, thereby obtaining a plurality of light-emitting elements ED. The light-emitting element cores ELC may be separated from the base substrate BSUB by a physical and/or chemical method, but the present disclosure is not limited thereto.

A display device including the light-emitting elements ED will hereinafter be described.

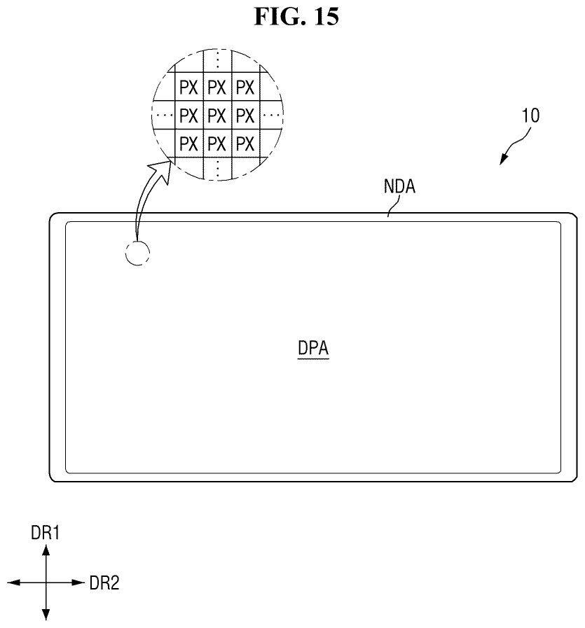

FIG. 15 is a plan view of a display device according to one or more embodiments of the present disclosure.

Referring to FIG. 15, a display device 10 displays a moving and/or still image. The display device 10 may refer to nearly all types (or kinds) of electronic devices that provide a display screen. Examples of the display device 10 may include a television (TV), a notebook computer, a monitor, a billboard, an Internet-of-Things (IoT) device, a mobile phone, a smartphone, a tablet personal computer (PC), an electronic watch, a smartwatch, a watchphone, a head-mounted display (HMD), a mobile communication terminal, an electronic notepad, an electronic book (e-book), a portable multimedia player (PMP), a navigation device, a gaming console, a digital camera, a camcorder, and the like.

The display device 10 includes a display panel that provides a display screen. Examples of the display panel of the display device 10 include an inorganic light-emitting diode (ILED) display panel, an organic light-emitting diode (OLED) display panel, a quantum-dot light-emitting diode (QLED) display panel, a plasma display panel (PDP), a field-emission display (FED) panel, and the like. The display panel of the display device 10 will hereinafter be described as being, for example, an ILED display panel, but the present disclosure is not limited thereto. That is, various other suitable display panels are also applicable to the display panel of the display device 10.

The shape of the display device 10 may vary. For example, the display device 10 may have a rectangular shape extending longer in a first direction DR1 than in a second direction DR2, a rectangular shape extending longer in the second direction DR2 than in the first direction DR1, a square shape, a quadrilateral shape with rounded corners, a non-quadrilateral polygonal shape, or a circular shape. The shape of a display area DPA of the display device 10 may be similar to the shape of the display device 10. FIG. 15 illustrates that the display device 10 has a rectangular shape extending longer in the second direction DR2 than in the first direction DR1.

The display device 10 may include the display area DPA and a non-display area NDA. The display area DPA may be an area in which a screen (e.g., an image) is displayed, and the non-display area NDA may be an area in which a screen (e.g., an image) is not displayed. The display area DPA may also be referred to as an active area, and the non-display area NDA may also be referred to as an inactive area. The display area DPA may occupy substantially the middle portion of the display device 10.

The display area DPA may include a plurality of pixels PX. The pixels PX may be arranged in row and column directions. The pixels PX may have a rectangular and/or square shape in a plan view, but the present disclosure is not limited thereto. In some embodiments, the pixels PX may have a rhombus shape having sides that are inclined with respect to a set or particular direction. The pixels PX may be alternately arranged with each other in a stripe fashion or as islands. Each of the pixels PX may include one or more light-emitting elements emitting (e.g., configured to emit) light of a set or particular wavelength range and may thus display a set or particular color.

The non-display area NDA may be provided around the display area DPA. The non-display area NDA may surround the entire display area DPA or portion of the display area DPA. The display area DPA may have a rectangular shape, and the non-display area NDA may be provided adjacent to four sides of the display area DPA. The non-display area NDA may form the bezel of the display device 10. Lines and/or circuit drivers included in the display device 10 may be provided in the non-display area NDA, and/or external devices may be mounted in the non-display area NDA.

The structure of a pixel PX of the display device 10 will hereinafter be described.

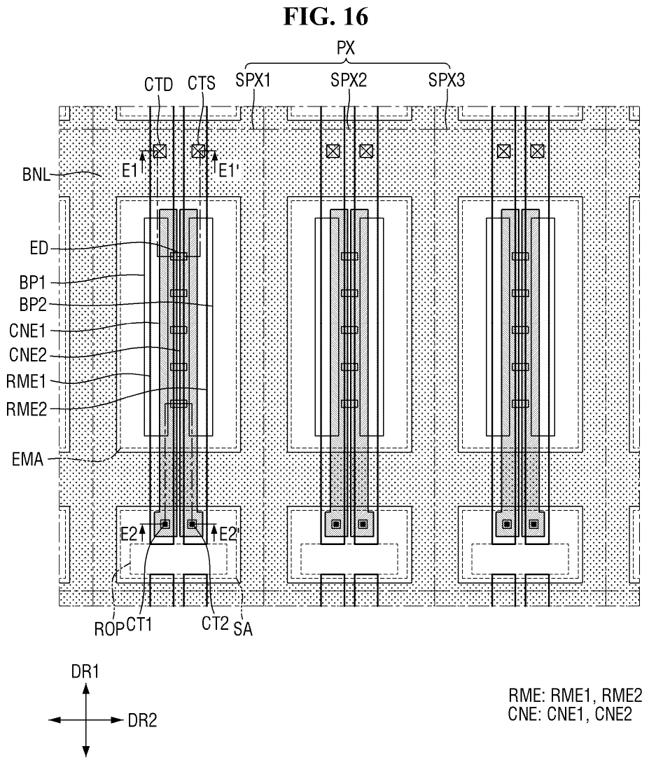

FIG. 16 is a plan view of a pixel of the display device of FIG. 15. FIG. 16 illustrates the layout of electrodes RME, bank patterns (BP1 and BP2), a bank layer BNL, a plurality of light-emitting elements ED, and connection electrodes CNE in each pixel PX.

Referring to FIG. 16, a pixel PX may include a plurality of subpixels SPXn. For example, the pixel PX may include first, second, and third subpixels SPX1, SPX2, and SPX3. The first, second, and third subpixels SPX1, SPX2, and SPX3 may emit light of first, second, and third colors, respectively. For example, the first, second, and third colors may be blue, green, and red, respectively, but the present disclosure is not limited thereto. In some embodiments, the first, second, and third subpixels SPX1, SPX2, and SPX3 may emit light of the same color. The subpixels SPXn may emit blue light. FIG. 16 illustrates that the pixel PX includes three subpixels SPXn, but the pixel PX may include more than three subpixels SPXn.

Each of the subpixels SPXn of the pixel PX may include an emission area EMA and a non-emission area. The emission area EMA may be an area where an array of light-emitting elements ED is provided and is configured to emit light. The non-emission area may be an area that is not reached by light emitted from the array of light-emitting elements ED and thus does not output light.

The emission area EMA of each of the subpixels SPXn may include an area where an array of light-emitting elements ED is provided and an area around the array of light-emitting elements ED that outputs light emitted from the array of light-emitting elements ED. For example, the emission area EMA of each of the subpixels SPXn may also include an area that outputs light emitted from the array of light-emitting elements ED and then reflected or refracted by other members. A plurality of light-emitting elements ED may be provided in each of the subpixels SPXn, and the emission area EMA of each of the subpixels SPXn may be configured to include an area where the plurality of light-emitting elements ED are provided and an area around the plurality of light-emitting elements ED.

The emission areas EMA of the subpixels SPXn are illustrated as having the same size, but the present disclosure is not limited thereto. In some embodiments, the emission areas EMA of the subpixels SPXn may have different sizes depending on the color and/or the wavelength range of light emitted from their respective arrays of light-emitting elements ED.

Each of the subpixels SPXn may further include a subarea SA, which is provided in the non-emission area. In each of the subpixels SPXn, the subarea SA may be provided on a lower side, in the first direction DR1, of the emission area EMA. Emission areas EMA and subareas SA may be arranged alternately with each other in the first direction DR1, and a subarea SA may be provided between the emission areas EMA of each pair of adjacent subpixels SPXn in the first direction DR1. For example, the emission areas EMA and the subareas SA may be arranged alternately with each other in the first direction DR1, and the emission areas EMA or the subareas SA may be repeatedly arranged in the second direction DR2. However, the present disclosure is not limited to this example. In some embodiments, the emission areas EMA and the subareas SA may have a different layout from that illustrated in FIG. 16.

The light-emitting elements ED are not provided in the subarea SA of each of the subpixels SPXn so that no light may be emitted from the subarea SA of each of the subpixels SPXn, and parts of the electrodes RME may be provided in the subarea SA of each of the subpixels SPXn. Different sets of electrodes RME provided in different subpixels SPXn may be separated from one another in separation parts ROP of subareas SA of the different subpixels SPXn.

Wiring and circuit elements of a circuit layer of the pixel PX that are connected to light-emitting elements ED may be connected to the first, second, and third subpixels SPX1, SPX2, and SPX3. The wiring and the circuit elements may not be provided to correspond to the area occupied by each of the subpixels SPXn or the emission area EMA of each of the subpixels SPXn, but may be arranged regardless of the location of the emission area EMA of each of the subpixels SPXn.

The bank layer BNL may be provided to surround the subpixels SPXn and the emission areas EMA and the subareas SA of the subpixels SPXn. The bank layer BNL may be provided along the boundaries between pairs of adjacent subpixels SPXn in the first direction DR1, the boundaries between pairs of adjacent subpixels SPXn in the second direction DR2, and the boundaries between the emission areas EMA and the subareas SA of the subpixels SPXn. The subpixels SPXn and the emission areas EMA and the subareas of the subpixels SPXn may be areas defined by the bank layer BNL. The distance between the subpixels SPXn and the distance between the emission areas EMA and the subareas SA of the subpixels SPXn may vary depending on the width of the bank layer BNL.

The bank layer BNL may include portions extending in the first direction DR1 and portions extending in the second direction DR2, in a plan view, and may be arranged in a lattice pattern over the entire surface of the display area DPA. The bank layer BNL may be provided along the boundaries between the subpixels SPXn to distinguish the subpixels SPXn from one another. Also, the bank layer BNL may be provided to surround the emission areas EMA and the subareas SA of the subpixels SPXn to distinguish the emission areas EMA and the subareas SA of the subpixels SPXn from one another.

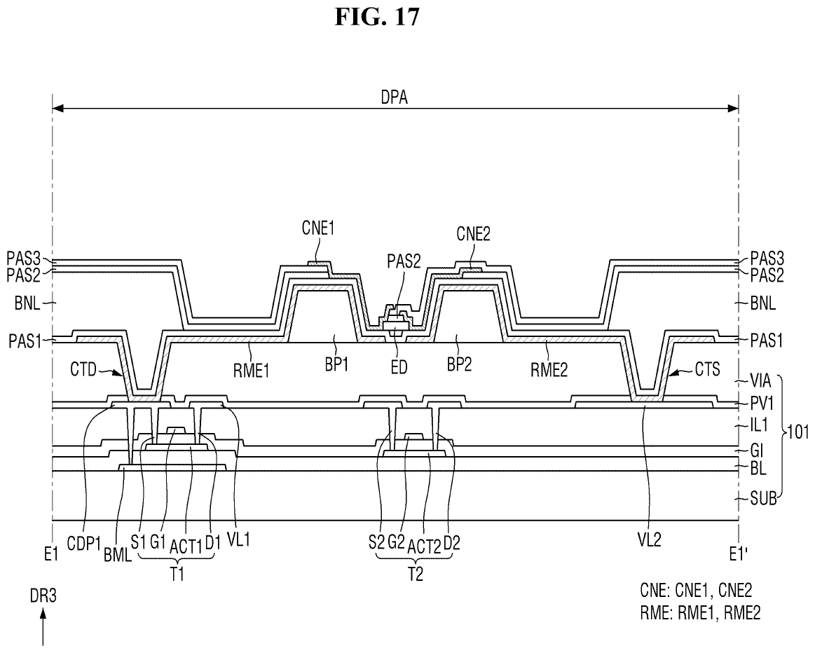

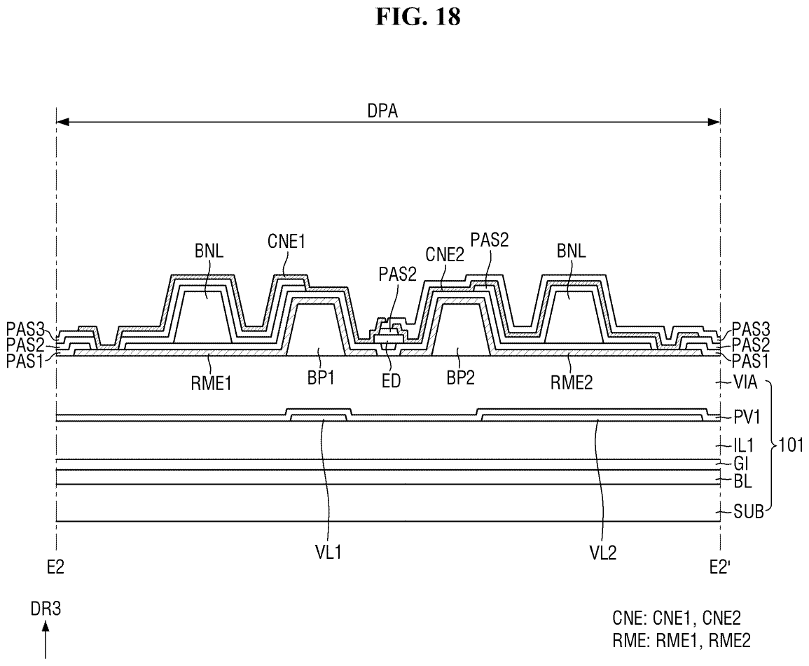

FIG. 17 is a cross-sectional view taken along line E1-E1′ of FIG. 16. FIG. 18 is a cross-sectional view taken along line E2-E2′ of FIG. 16. FIG. 17 illustrates a cross-sectional view taken across a light-emitting element ED and first and second electrode contact holes CTD and CTS of the first subpixel SPX1 of FIG. 16, and FIG. 18 illustrates a cross-sectional view taken across another light-emitting element ED and first and second contacts CT1 and CT2 of the first subpixel SPX1 of FIG. 16.

Referring to FIGS. 17 and 18 and further to FIG. 16, the display device 10 may include, in each of the subpixels SPXn, for example, in the first subpixel SPX1, a wiring substrate 101, and the wiring substrate 101 may include a first substrate SUB and a semiconductor layer, a plurality of conductive layers, and a plurality of insulating layers, which are provided on the first substrate SUB. The display device 10 may further include a plurality of electrodes RME, light-emitting elements ED, and connecting electrodes CNE, which are provided on the wiring substrate 101. The semiconductor layer, the conductive layers, and the insulating layers of the wiring substrate 101 may form a circuit layer of the display device 10.

The first substrate SUB may be an insulating substrate. The substrate SUB may be formed of an insulating material such as glass, quartz, and/or a polymer resin. The substrate SUB may be a rigid substrate or may be a flexible substrate that is bendable, foldable, and/or rollable. The first substrate SUB may include a display area DPA and a non-display area NDA, which surrounds the display area DPA, and the display area DPA may include an emission area EMA and a subarea SA, which is portion of a non-emission area.

A first conductive layer may be provided on the first substrate SUB. The first conductive layer includes a lower metal layer BML, and the lower metal layer BML is provided to overlap with a first active layer ACT1 of a first transistor T1. The lower metal layer BML may prevent or reduce incident light upon the first active layer ACT1 of the first transistor T1 and/or may be electrically connected to the first active layer ACT1 to stabilize (or suitably stabilize) the electrical characteristics of the first transistor T1. The lower metal layer BML may be optional (e.g., may not be provided).

A buffer layer BL may be provided on the lower metal layer BML and the first substrate SUB. The buffer layer BL may be formed on the first substrate SUB to protect transistors of, for example, the first subpixel SPX1, for example, the first transistor T1 and a second transistor T2, and may perform a surface planarization function.

The semiconductor layer may be provided on the buffer layer BL. The semiconductor layer may include the first active layer ACT1 of the first transistor T1 and a second active layer ACT2 of the second transistor T2. The first and second active layers ACT1 and ACT2 may be provided to partially overlap with first and second gate electrodes G1 and G2, respectively, of a second conductive layer that will be described in more detail hereinbelow.

The semiconductor layer may include polycrystalline silicon, monocrystalline silicon, and/or an oxide semiconductor. In some embodiments, the semiconductor layer may include polycrystalline silicon. The oxide semiconductor may be an oxide semiconductor containing indium (In). For example, the oxide semiconductor may be at least one selected from among ITO, IZO, indium gallium oxide (IGO), indium zin tin oxide (IZTO), indium gallium tin oxide (IGTO), and indium gallium zinc tin oxide (IGZTO).

FIGS. 17 and 18 illustrate that the first subpixel SPX1 includes only two transistors, for example, the first and second transistors T1 and T2, but the present disclosure is not limited thereto. In some embodiments, the first subpixel SPX1 may include more than two transistor.

A first gate insulating layer GI is provided on the semiconductor layer and the buffer layer BL, in the display area DPA. The first gate insulating layer GI may not be provided in a pad area PDA. The first gate insulating layer GI may function as the gate insulating films of the first and second transistors T1 and T2. The first gate insulating layer GI is illustrated as being provided on the entire surface of the buffer layer BL, but the present disclosure is not limited thereto. In some embodiments, the first gate insulating layer GI may be patterned together with the first and second gate electrodes G1 and G2 of the second conductive layer and may thus be provided in part between the first and second active layers ACT1 and ACT2 of the semiconductor layer.

The second conductive layer is provided on the first gate insulating layer GI. The second conductive layer may include the first and second gate electrodes G1 and G2 of the first and second transistors T1 and T2. The first gate electrode G1 may be provided to overlap with a channel region of the first active layer ACT1 in a third direction DR3, and the second gate electrode G2 may be provided to overlap with a channel region of the second active layer ACT2 in the third direction DR3. In some embodiments, the second conductive layer may further include a first electrode of a storage capacitor.

A first interlayer insulating layer IL1 is provided on the second conductive layer. The first interlayer insulating layer IL1 may function as an insulating film between the second conductive layer and layers provided on the second conductive layer and may protect the second conductive layer.

A third conductive layer is provided on the first interlayer insulating layer IL1. The third conductive layer may include first and second voltage lines VL1 and VL2, a first conductive pattern CDP1, and first and second source electrodes S1 and S2 and first and second drain electrodes D1 and D2 of the first and second transistors T1 and T2, which are provided in the display area DPA. In some embodiments, the third conductive layer may further include a second electrode of the storage capacitor.

A high-potential voltage (or a first power supply voltage), which is to be transmitted to a first electrode RME1, may be applied to the first voltage line VL1, and a low-potential voltage (or a second power supply voltage), which is to be transmitted to a second electrode RME2, may be applied to the second voltage line VL2. Portion of the first voltage line VL1 may be in contact with the first active layer ACT1 of the first transistor T1 through a contact hole penetrating the first interlayer insulating layer IL1 and the first gate insulating layer GI. The first voltage line VL1 may function as the first drain electrode D1 of the first transistor T1. The second voltage line VL2 may be directly connected to the second electrode RME2.

The first conductive pattern CDP1 may be in contact with the first active layer ACT1 of the first transistor T1 through a contact hole penetrating the first interlayer insulating layer IL1 and the first gate insulating layer GI. The first conductive pattern CDP1 may be in contact with the lower metal layer BML through another contact hole. The first conductive pattern CDP1 may function as the first source electrode S1 of the first transistor T1. The first conductive pattern CDP1 may be connected to the first electrode RME1 or a first connection electrode CNE1. The first transistor T1 may transmit the first power supply voltage from the first voltage line VL1 to the first electrode REM1 or the first connection electrode CNE1.

The second source electrode S2 and the second drain electrode D2 may be in contact with the second active layer ACT2 of the second transistor T2 through contact holes penetrating the first interlayer insulating layer IL1 and the first gate insulating layer GI. The second transistor T2 may be a switching transistor.

A first passivation layer PV1 is provided on the third conductive layer. The first passivation layer PV1 may function as an insulating film between the third conductive layer and layers provided on the third conductive layer and may protect the third conductive layer.

Each selected from among the buffer layer BL, the first gate insulating layer G1, the first interlayer insulating layer IL1, and the first passivation layer PV1 may include a plurality of inorganic layers that are alternately stacked. For example, each selected from among the buffer layer BL, the first gate insulating layer GI, the first interlayer insulating layer IL1, and the first passivation layer PV1 may be formed as a double layer or a multilayer in which inorganic layers including at least one selected from among SiOₓ, SiNₓ, and SiOₓN_{y} are alternately stacked, but the present disclosure is not limited thereto. In some embodiments, each selected from among the buffer layer BL, the first gate insulating layer GI, the first interlayer insulating layer IL1, and the first passivation layer PV1 may be formed as a single inorganic layer including at least one selected from among SiOₓ, SiNₓ, and SiOₓN_{y}. In some embodiments, the first interlayer insulating layer IL1 may be formed of an organic insulating material such as polyimide (PI).

A via layer VIA is provided on the third conductive layer, in the display area DPA. The via layer VIA may include an organic insulating material such as, for example, PI, and may thus be able to planarize (or substantially or suitably planarize) height differences formed by the underlying conductive layers and planarize (or substantially or suitably planarize) the tops of the underlying conductive layers. The via layer VIA may be optional (e.g., may not be provided).

The display device 10 may include, as a display element layer on the via layer VIA on the wiring substrate 101, the bank patterns (BP1 and BP2), the electrodes RME, the bank layer BNL, the light-emitting elements ED, and the connection electrodes CNE. The display device 10 may also include a plurality of insulating layers, e.g., first, second, and third insulating layers PAS1, PAS2, and PAS3.

The bank patterns (BP1 and BP2) may be provided in the emission area EMA. The bank patterns (BP1 and BP2) may have a set or predetermined width in the second direction DR2 and may extend in the first direction DR1.

For example, the bank patterns (BP1 and BP2) may include first and second bank patterns BP1 and BP2, which are spaced apart from each other in the second direction DR2 in the emission area EMA. The first bank pattern BP1 may be provided on one side, in the second direction DR2, of the center of the emission area EMA, for example, on the left side of the center of the emission area EMA, and the second bank pattern BP2 may be provided on the other side, in the second direction DR2, of the center of the emission area EMA, for example, on the right side of the emission area EMA. First bank patterns BP1 and second bank patterns BP2 may be alternately arranged with each other in the second direction DR2 and may be arranged as island patterns in the display area DPA. A plurality of light-emitting elements ED may be provided between the first and second bank patterns BP1 and BP2.

The first and second bank patterns BP1 and BP2 may have the same length in the first direction DR1 and may have a smaller length in the first direction DR1 than the emission area EMA surrounded by the bank layer BNL. The first and second bank patterns BP1 and BP2 of each of the subpixels SPXn may be spaced apart from the portions of the bank layer BNL that extend in the second direction DR2, but the present disclosure is not limited thereto. In some embodiments, the first and second bank patterns BP1 and BP2 may be integrally formed with the bank layer BNL or may partially overlap with the portions of the bank layer BNL that extend in the second direction DR2, in which case, the length, in the first direction DR1, of the bank patterns (BP1 and BP2) may be the same as, or greater than, the length, in the first direction DR1, of the emission area EMA surrounded by the bank layer BNL.

The first and second bank patterns BP1 and BP2 may have the same width in the second direction DR2, but the present disclosure is not limited thereto. In some embodiments, the first and second bank patterns BP1 and BP2 may have different widths in the second direction DR2, and whichever of the first and second bank patterns BP1 and BP2 has a greater width than the other bank pattern in the second direction DR2 may be provided not only in the emission area EMA of the first subpixel SPX1, but also in the emission area EMA of a neighboring subpixel SPX adjacent to the first subpixel SPX1 in the second direction DR2 and may overlap with a portion of the bank layer BNL extending in the first direction DR1 in a thickness direction. The first subpixel SPX1 is illustrated as having two bank patterns, e.g., the first and second bank patterns BP1 and BP2, which have the same width, but the present disclosure is not limited thereto. The number and the layout of bank patterns (BP1 and BP2) may vary depending on the number and the layout of electrodes RME.

The bank patterns (BP1 and BP2) may be provided on the via layer VIA. For example, the bank patterns (BP1 and BP2) may be provided directly on the via layer VIA and may at least partially protrude from the top surface of the via layer VIA. Each of protruding parts of the bank patterns (BP1 and BP2) may have inclined and/or curved side surfaces, and light emitted from the light-emitting elements ED may be reflected by the electrodes RME, which are provided on the bank patterns (BP1 and BP2), and may thus be output in an upward direction from the via layer VIA. In some embodiments, the outer surfaces (e.g., outer peripheral surfaces) of each of the bank patterns (BP1 and BP2) may have a semicircular or semielliptical shape in a cross-sectional view. The bank patterns (BP1 and BP2) may include an organic insulating material such as PI, but the present disclosure is not limited thereto.

The electrodes RME may be provided in each of the subpixels SPXn, e.g., in the first subpixel SPX1, and may extend in one direction. The electrodes RME may extend in the first direction DR1 and may be provided in the emission area EMA and the subarea SA and may be spaced apart from each other in the second direction DR2. The electrodes RME may be electrically connected to the light-emitting elements ED that will be described in more details herein below. In some embodiments, the electrodes RME may not be electrically connected to the light-emitting elements ED.

The electrodes RME may include first and second electrodes RME1 and RME2, which are provided in each of the subpixels SPXn, e.g., in the first subpixel SPX1. The first electrode RME1 may be provided on the left side of the center of the emission area EMA, and the second electrode RME2 may be spaced apart from the first electrode RME1 and may be provided on the right side of the center of the emission area EMA. The first electrode RME1 may be provided on the first bank pattern BP1, and the second electrode RME2 may be provided on the second bank pattern BP2. The first and second electrodes RME1 and RME2 may be provided in part in the subarea SA, beyond the bank layer BNL. Different sets of first and second electrodes RME1 and RME2 of different subpixels SPXn may be spaced apart from one another by a separation part ROP in the subarea SA of one of the different subpixels SPXn.

The first subpixel SPX1 is illustrated as having two electrodes, e.g., the first and second electrodes RME1 and RME2, which extend in the first direction DR1, but the present disclosure is not limited thereto. In some embodiments, the electrodes RME may be bent in part or may have different widths from one location to another location.

The first and second electrodes RME1 and RME2 may be provided on inclined side surfaces of the bank patterns (BP1 and BP2). The width, in the second direction DR2, of the electrodes RME may be less than the width, in the second direction DR2, of the bank patterns (BP1 and BP2), and the distance between the first and second electrodes RME1 and RME2 may be less than the distance between the first and second bank patterns BP1 and BP2. At least parts of the first and second electrodes RME1 and RME2 may be provided directly on the via layer VIA and may thus fall on the same plane.

The light-emitting elements ED provided between the bank patterns (BP1 and BP2) may emit light through both ends thereof, and the emitted light may proceed toward the electrodes RME on the bank patterns (BP1 and BP2). Parts of the electrodes RME on the bank patterns (BP1 and BP2) may have a structure capable of reflecting light emitted from the light-emitting elements ED. The first and second electrodes RME1 and RME2 may be provided to cover side surfaces of at least the bank patterns (BP1 and BP2) and may thus be able to reflect light emitted from the light-emitting elements ED.

The electrodes RME may be in direct contact with the third conductive layer through the first and second electrode contact holes CTD and CTS in an area overlapping with the bank layer BNL, between the emission area EMA and the subarea SA. The first electrode contact hole CTD may be formed in an area where the bank layer BNL and the first electrode RME1 overlap with each other, and the second electrode contact hole CTS may be formed in an area where the bank layer BNL and the second electrode RME2 overlap with each other. The first electrode RME1 may be in contact with the first conductive pattern CDP1 through the first electrode contact hole CTD, which penetrates the via layer VIA and the first passivation layer PV1. The second electrode RME2 may be in contact with the second voltage line VL through the second electrode contact hole CTS, which penetrates the via layer VIA and the first passivation layer PV1. The first electrode RME1 may be electrically connected to the first transistor T1 through the first conductive pattern CDP1 so that the first power supply voltage may be applied to the first electrode RME1, and the second electrode RME2 may be electrically connected to the second voltage VL2 so that the second power supply voltage may be applied to the second electrode RME2. However, the present disclosure is not limited to this. In some embodiments, the first and second electrodes RME1 and RME2 may not be electrically connected to the first and second voltage lines VL1 and VL2, and the connection electrodes CNE may be directly connected to the third conductive layer.

The electrodes RME may include a conductive material with a suitably high reflectance. For example, the electrodes RME may include a metal such as Ag, copper (Cu), and/or Al, an alloy of Al, nickel (Ni), and/or lanthanum (La), and/or a stack of a metal such as Ti, molybdenum (Mo), and/or niobium (Nb) and an alloy of Al, Ni, and/or La. In some embodiments, the electrodes RME may be formed as double layers or multilayers in which at least one layer of an alloy of Al and a metal such as Ti, Mo, and/or Nb is stacked.

However, the present disclosure is not limited to this. In some embodiments, the electrodes RME may include a transparent conductive material. For example, the electrodes RME may include a material such as ITO, IZO, and/or ITZO. In some embodiments, the electrodes RME may have a structure in which at least one layer of the transparent conductive material and at least one layer of a metal with high reflectance are stacked or a structure of single layer(s) including both the transparent conductive material and the metal with high reflectance. For example, the electrodes RME may have a stack structure such as ITO/Ag/ITO, ITO/Ag/IZO, or ITO/Ag/ITZO/IZO. The electrodes RME may be electrically connected to the light-emitting elements ED and may reflect some of the light emitted from the light-emitting elements ED in an upward direction from the first substrate SUB.

The first insulating layer PAS1 may be provided on the entire surface of the display area DPA, on the via layer VIA and the electrodes RME. The first insulating layer PAS1 may protect the electrodes RME and may insulate the electrodes RME from each other. As the first insulating layer PAS1 is provided to cover the electrodes RME before the formation of the bank layer BNL, the first insulating layer PAS1 can prevent or reduce damage to the electrodes RME during the formation of the bank layer BNL. Also, the first insulating layer PAS1 can prevent or reduce damage to the light-emitting elements ED from being placed in direct contact with other members.

The first insulating layer PAS1 may be formed to have a recessed top surface between the electrodes RME, which are spaced apart from each other in the second direction DR2. The light-emitting elements ED may be provided on the recessed top surface of the first insulating layer PAS1, and space may be formed between the first insulating layer PAS1 and the light-emitting elements ED.

The bank layer BNL may be provided on the first insulating layer PAS1. The bank layer BNL may include portions extending in the first direction DR1 and portions extending in the second direction DR2 and may surround each of the subpixels SPXn. The bank layer BNL may surround the emission area EMA and the subarea SA of each of the subpixels SPXn to distinguish the emission area EMA and the subarea SA of each of the subpixels SPXn, and may surround the outermost periphery of the display area DPA to distinguish the display area DPA and the non-display area NDA. The bank layer BNL may be provided on the entire surface of the display area DPA to form a lattice pattern, and openings formed in the display area DPA by the bank layer BNL may include the emission area EMA and the subarea SA of each of the subpixels SPXn.

The bank layer BNL, like the bank patterns (BP1 and BP2), may have a set or predetermined height. In some embodiments, the height of the top surface of the bank layer BNL may be greater than the height of the bank patterns (BP1 and BP2), and the thickness of the bank layer BNL may be the same as, or greater than, the thickness of the bank patterns (BP1 and BP2). The bank layer BNL may prevent or reduce the spilling of the ink from an inkjet printing process out of each of the subpixels SPXn during the fabrication of the display device 10. The bank layer BNL, like the bank patterns (BP1 and BP2), may include an organic insulating material such as PI.

The light-emitting elements ED may be provided in the emission area EMA. The light-emitting elements ED may be provided between the bank patterns (BP1 and BP2) and may be spaced apart from one another in the first direction DR1. The light-emitting elements ED may extend in one direction, and both end portions of each of the light-emitting elements ED may be provided on different electrodes RME. The length of the light-emitting elements ED may be greater than the distance, in the second direction DR2, between the electrodes RME. The direction in which the light-emitting elements ED extend may be substantially perpendicular to the first direction DR1, but the present disclosure is not limited thereto. In some embodiments, the direction in which the light-emitting elements ED extend may be parallel (or substantially parallel) to, or at an inclination with respect to, the second direction DR2.

The light-emitting elements ED may be provided on the first insulating layer PAS1. The light-emitting elements ED may extend in one direction, and the direction in which the light-emitting elements ED extend may be parallel (or substantially parallel) to the top surface of the first substrate SUB. As will be described in more detail herein below, each of the light-emitting elements ED may include a plurality of semiconductor layers, which are arranged in the direction in which the light-emitting elements ED extend, and the plurality of semiconductor layers may be sequentially arranged in a direction parallel (or substantially parallel) to the top surface of the first substrate SUB. However, the present disclosure is not limited to this. In some embodiments, the plurality of semiconductor layers may be arranged in a direction perpendicular (or substantially perpendicular) to the first substrate SUB.

The wavelength of light emitted by the light-emitting elements ED may vary depending on the material of the plurality of semiconductor layers so that different subpixels SPXn may emit light of different wavelength ranges. However, the present disclosure is not limited to this. In some embodiments, the plurality of semiconductor layers of each of the light-emitting elements ED of each of the subpixels SPXn may all be formed of the same material throughout so that different subpixels SPXn may all emit light of the same color.

The light-emitting elements ED may be in contact with the connection electrodes CNE and may thus be electrically connected to the electrodes RME and the conductive layers below the via layer VIA and emit light of a set or particular wavelength range in response to the application of electrical signals thereto.

As described above with reference to FIGS. 2 and 3, each of the light-emitting elements ED may include an active layer 36, and the active layer 36 may include a cove layer 52 in which a plurality of quantum dots 54 are distributed. As the quantum dots 54 are distributed, the contact areas of the quantum dots 54 and the side surface of the active layer 36 can be reduced, and as a result, a decrease in the luminous efficiency of each of the light-emitting elements ED can be prevented or reduced. Also, as the quantum dots 54 are spaced apart from one another, carriers can be confined (or substantially confined) within the quantum dots 54 without flowing out of the quantum dots 54. Accordingly, carriers can be concentrated (or substantially concentrated) within the quantum dots 54, and thus, the luminance of the light-emitting elements ED can be improved.

The second insulating layer PAS2 may be provided on the light-emitting elements ED, the first insulating layer PAS1, and the bank layer BNL. The second insulating layer PAS2 may include pattern parts, which extend in the first direction DR1 between the bank patterns (BP1 and BP2) and are provided on the light-emitting elements ED. The pattern parts may surround parts of the outer surfaces of each of the light-emitting elements ED, but may not cover both ends (e.g., both end portions) of each of the light-emitting elements ED. The pattern parts may form linear and/or island patterns in each of the subpixels SPXn, e.g., in the first subpixel SPX1, in a plan view. The pattern parts of the second insulating layer PAS2 may protect and fix (e.g., affix) the light-emitting elements ED during the fabrication of the display device 10. The second insulating layer PAS2 may also be provided to fill the space between the light-emitting elements ED and the first insulating layer PAS1. The second insulating layer PAS2 may also be provided in part on the bank layer BNL and in the subarea SA.

The connection electrodes CNE may be provided on the electrodes RME and the bank patterns (BP1 and BP2). The connection electrodes CNE may extend in one direction and may be spaced apart from one another. The connection electrodes CNE may be in contact with the light-emitting elements ED and may be electrically connected to the third conductive layer.

The connection electrodes CNE may include first and second connection electrodes CNE1 and CNE2, which are provided in each of the subpixels SPXn, e.g., in the first subpixel SPX1. The first connection electrode CNE1 may extend in the first direction DR1 and may be provided on the first electrode RME1 and/or the first bank pattern BP1. The first connection electrode CNE1 may partially overlap with the first electrode RME1 and may be provided not only in the emission area EMA, but also in the subarea SA, beyond the bank layer BNL. The second connection electrode CNE2 may extend in the first direction DR1 and may be provided on the second electrode RME2 and/or the second bank pattern BP2. The second connection electrode CNE2 may partially overlap with the second electrode RME2 and may be provided not only in the emission area EMA, but also in the subarea SA, beyond the bank layer BNL. The first and second connection electrodes CNE1 and CNE2 may be in contact with the light-emitting elements ED and may be electrically connected to the electrodes RME and the underlying conductive layers.

For example, the first and second connection electrodes CNE1 and CNE2 may be provided on side surfaces of the second insulating layer PAS2 and may thus be in contact with the light-emitting elements ED. The first connection electrode CNE1 may partially overlap with the first electrode RME1 and may be in contact with first end portions of the light-emitting elements ED. The second connection electrode CNE2 may partially overlap with the second electrode RME2 and may be in contact with second end portions of the light-emitting elements ED. The connection electrodes CNE may be provided in both the emission area EMA and the subarea SA. The connection electrodes CNE may be in contact with the light-emitting elements ED, in the emission area EMA, and may be electrically connected to the third conductive layer, in the subarea SA.

The connection electrodes CNE may be in contact with the electrodes RME through the first and second contacts CT1 and CT2, which are provided in the subarea SA. The first connection electrode CNE1 may be in contact with the first electrode RME1 through the first contact CT1, which penetrates the first, second, and third insulating layers PAS1, PAS2, and PAS3, in the subarea SA. The second connection electrode CNE2 may be in contact with the second electrode RME2 through the second contact CT2, which penetrates the first and second insulating layers PAS1 and PAS2, in the subarea SA. The connection electrodes CNE may be electrically connected to the third conductive layer through the electrodes RME. The first connection electrode CNE1 may be electrically connected to the first transistor T1 and may thus receive the first power supply voltage, and the second connection electrode CNE2 may be electrically connected to the second voltage line VL2 and may thus receive the second power supply voltage. The connection electrodes CNE may be in contact with the light-emitting elements ED, in the emission area EMA, and may thus transmit the first and second power supply voltages to the light-emitting elements ED.

However, the present disclosure is not limited to this. In some embodiments, the connection electrodes CNE may be in direct contact with the third conductive layer or may be electrically connected to the third conductive layer through patterns other than the electrodes RME.

The connection electrodes CNE may include a conductive material. For example, the connection electrodes CNE may include ITO, IZO, ITZO, and/or Al. For example, the connection electrodes CNE may include a transparent conductive material, and light emitted from the light-emitting elements ED may be output through the connection electrodes CNE.

The third insulating layer PAS3 is provided on the second connection electrode CNE2 and the second insulating layer PAS2. The third insulating layer PAS3 may be provided on the entire surface of the second insulating layer PAS2 to cover the second connection electrode CNE2, and the first connection electrode CNE1 may be provided on the third insulating layer PAS3. The third insulating layer PAS3 may be provided on the entire surface of the via layer VIA except for an area where the second connection electrode CNE2 is provided. The third insulating layer PAS3 may insulate the first and second connection electrodes CNE1 and CNE2 from one another for the first and second connection electrodes CNE1 and CNE2 not to be in direct contact with each other.

In one or more embodiments, another (e.g., additional) insulating layer may be further provided on the third insulating layer PAS3 and the first connection electrode CNE1. The (additional) insulating layer may protect the members provided on the first substrate SUB from an external environment.

The first, second, and third insulating layers PAS1, PAS2, and PAS3 may include an inorganic and/or organic insulating material. For example, the first, second, and third insulating layers PAS1, PAS2, and PAS3 may include an inorganic insulating material. In some embodiments, the first and third insulating layers PAS1 and PAS3 may include an inorganic insulating material, and the second insulating layer PAS2 may include an organic insulating material. In some embodiments, at least one selected from among the first, second, and third insulating layers PAS1, PAS2, and P PAS3 may have a structure in which a plurality of insulating layers are alternately or repeatedly stacked. The first, second, and third insulating layers PAS1, PAS2, and PAS3 may include one selected from among SiOₓ, SiNₓ, and SiOₓN_{y}. The first, second, and third insulating layers PAS1, PAS2, and PAS3 may all be formed of the same material or different materials, or some of the first, second, and third insulating layers PAS1, PAS2, and PAS3 may be formed of the same material.

In concluding the detailed description, those skilled in the art will appreciate that many variations and modifications can be made to the present embodiments without substantially departing from the principles of the present disclosure as set forth in the following claims and their equivalents. Therefore, the disclosed embodiments are used in a generic and descriptive sense only and not for purposes of limitation.

What is claimed is:

1. A light-emitting element comprising:
a first semiconductor layer;
an active layer on the first semiconductor layer;
a second semiconductor layer on the active layer;
an electrode layer on the second semiconductor layer; and
an insulating film around outer peripheral surfaces of the first semiconductor layer, the active layer, the second semiconductor layer, and the electrode layer,
wherein:
the active layer comprises a cover layer comprising a plurality of quantum dots, and
the first semiconductor layer, the active layer, the second semiconductor layer, and the electrode layer are sequentially stacked in one direction to form a shape of a rod.

2. The light-emitting element of claim 1, wherein the light-emitting element is formed in a shape of a cylindrical rod or a hexagonal rod.

3. The light-emitting element of claim 1, wherein a diameter of the rod is in a range of 0.2 μm to 1 μm.

4. The light-emitting element of claim 1, wherein the plurality of quantum dots and the cover layer comprise InₓGa₁₋ₓN, where x is 0.1 to 0.3.

5. The light-emitting element of claim 4, wherein an indium (In) content of the plurality of quantum dots is different from an indium (In) content of the cover layer.

6. The light-emitting element of claim 5, wherein the In content of the plurality of quantum dots is greater than the In content of the cover layer.

7. The light-emitting element of claim 1, wherein the plurality of quantum dots are spaced apart at random intervals.

8. The light-emitting element of claim 1, wherein a thickness of each of the plurality of quantum dots is in a range of 1 nm to 5 nm.

9. The light-emitting element of claim 1, wherein a size of each of the plurality of quantum dots is in a range of 1 nm to 500 nm.

10. The light-emitting element of claim 1, wherein the active layer has a structure in which a plurality of cover layers, each of the plurality of cover layers comprising a plurality of quantum dots, are stacked.

11. A method of forming a light-emitting element, comprising:
forming a buffer layer on a base substrate;
forming a first semiconductor material layer on the buffer layer;
forming a cover layer comprising a plurality of quantum dots to form an active material layer on the first semiconductor material layer;
forming a second semiconductor material layer on the active material layer;
forming an electrode material layer on the second semiconductor material layer;
forming a light-emitting element core by etching the first semiconductor material layer, the active material layer, the second semiconductor material layer, and the electrode material layer;
forming an insulating film around the light-emitting element core; and
separating the light-emitting core and the insulating film from the buffer layer.

12. The method of claim 11, wherein the forming the active material layer comprises forming the plurality of quantum dots by lowering the temperature while forming the cover layer on the first semiconductor material layer.

13. The method of claim 12, wherein the plurality of quantum dots are formed at a temperature of more than or equal to 600° C. to less than 680° C.

14. The method of claim 11, wherein
the light-emitting element core comprises a first semiconductor layer, an active layer, a second semiconductor layer, and an electrode layer, and
the insulating film is around outer peripheral surfaces of the first semiconductor layer, the active layer, the second semiconductor layer, and the electrode layer.

15. The method of claim 11, wherein the light-emitting element core is formed in a shape of a cylindrical rod or a hexagonal rod.

16. A display device comprising:
a substrate;
a first electrode and a second electrode on the substrate spaced apart from each other, the first electrode and the second electrode extending substantially in parallel to each other;
an insulating layer on the first electrode and the second electrode;
light-emitting elements on the insulating layer and aligned on the first electrode and the second electrode; and
a first connection electrode connected to first end portions of the light-emitting elements and a second connection electrode connected to second end portions of the light-emitting elements,
wherein:
each of the light-emitting elements comprises a first semiconductor layer, an active layer on the first semiconductor layer, a second semiconductor layer on the active layer, an electrode layer on the second semiconductor layer, and an insulating film around outer peripheral surfaces of the first semiconductor layer, the active layer, the second semiconductor layer, and the electrode layer,
the active layer comprises a cover layer comprising a plurality of quantum dots, and
the first semiconductor layer, the active layer, the second semiconductor layer, and the electrode layer are sequentially stacked in one direction to form a shape of a rod.

17. The display device of claim 16, wherein the light-emitting element is formed in a shape of a cylindrical rod or a hexagonal rod.

18. The display device of claim 16, wherein
the plurality of quantum dots and the cover layer comprise InₓGa₁₋ₓN, where x is 0.1 to 0.3, and
an indium (In) content of the plurality of quantum dots is different from an indium (In) content of the cover layer.

19. The display device of claim 16, wherein
a thickness of each of the plurality of quantum dots is in a range of 1 nm to 5 nm, and
a size of each of the plurality of quantum dots is in a range of 1 nm to 500 nm.

20. The display device of claim 16, wherein the active layer has a structure in which a plurality of cover layers, each of the plurality of cover layers comprising a plurality of quantum dots, are stacked.
